(19) United States
(12) Patent Application Publication
(10) Pub. No.: US 2015/0144389 A1
(43) Pub. Date: May 28, 2015

(54) METHOD OF MINIMIZING MOLD FLASH DURING DAMBAR CUT

(71) Applicant: TEXAS INSTRUMENTS INCORPORATED, Dallas, TX (US)

(72) Inventors: Lee Han Meng @Eugene Lee, Melaka (MY); Kok Leong Yeo, Melaka (MY)

(21) Appl. No.: 14/087,781

(22) Filed: Nov. 22, 2013

(51) Int. Cl. H01L 23/495

(52) U.S. Cl. CPC H01L 23/495
USPC 174/261

(57) ABSTRACT

A method of reducing the amount of mold flash created during the molding process of a molded integrated circuit package by extending a protrusion from the leadframe dambar into the mold flash area.

### FIELD OF THE INVENTION

The present invention relates generally to semiconductor devices, and more particularly to a method and apparatus for minimizing the mold flash enclosed within the dambar and the package body.

### BACKGROUND OF THE INVENTION

This invention relates to the assembling and packaging of integrated circuit devices and, more particularly, to a lead frame for such devices, a method for minimizing the mold flash enclosed within the dambar and the package body.

Integrated circuits in the form of semiconductor dies are first attached to a support pad of the lead frame. Contact or bond pads on the semiconductor device are then individually attached by wire bonding to corresponding contact pads on the ends of the leads.

After the wire bonding operation is completed, the lead frame is placed in a mold. The mold is provided with a reservoir a quantity of insulating, molding compound. The molding compound is injected into the mold in order to encapsulate the circuit.

It is found useful by those skilled in the art to form the lead frames in a continuous strip. Each lead frame strip has an integrated circuit device attached to support pad as mentioned above. The support pads are themselves supported by two parallel siderails. Each siderail is located in the plane of the lead frame and on opposite sides of the die pad.

In the molding operation, mold cavities are formed around the lead frames to tightly close and seal upon themselves as well as the dam bar. The dam bar has a transverse portion that extends between pairs of adjoining leads. The dam bar restricts the flow of encapsulation material from the enclosed lead frame. After encapsulation, the dam bar and a portion of the mold flashing projecting between adjoining leads is removed by a punch. The punch is the typical metal punch that readily severs the metallic dam bar and also removes a portion of the projected mold flashing from between the leads of the lead frame.

During dambar cut, this mold flash will break and tend to leave some loose mold flash. The loose mold flashes that dropped during dambar cut and trim/form processes will cause quality issue such as dented lead, lead contamination (embedded with loose mold flash) and bend lead. The loose mold flash will sometimes cause damage to dambar cut and trim/form tools as well.

As such, there has arisen a need for a method of providing reduced mold flash between the package body and the dambar. An improved lead frame for providing reduced mold flash between the package body and the dambar is needed.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the present application, a molded semiconductor package is provided. The molded semiconductor package comprises: a molded portion of the package, having an edge; a leadframe having first and second surfaces and a thickness therebetween and a plurality of leads; a dam bar separated from the molded portion of the package edge, the dam bar having transverse portions extending between the adjoining leads of the plurality of leads; and projections of leadframe material extending inwardly from the dambar toward the edge of the molded portion of the package, wherein the projections are centered and spaced apart from the adjoining leads of the plurality of leads.

### DESCRIPTION OF THE VIEWS OF THE DRAWING

FIG. 1 is a top view of typical package detailing the mold flash area.

FIG. 2A is a top view of an embodiment of the disclosed package detailing the mold flash area and the projections on the leadframe.

FIG. 2B is a top view of the leadframe of FIG. 2A with molded body of the package covering the internal structure.

FIG. 3 is a top view of an embodiment of the disclosed package detailing the mold flash area and the projections on the leadframe and the configuration of the punch die.

In the drawings, like reference numerals are sometimes used to designate like structural elements. It should also be appreciated that the depictions in the figures are diagrammatic and not to scale.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

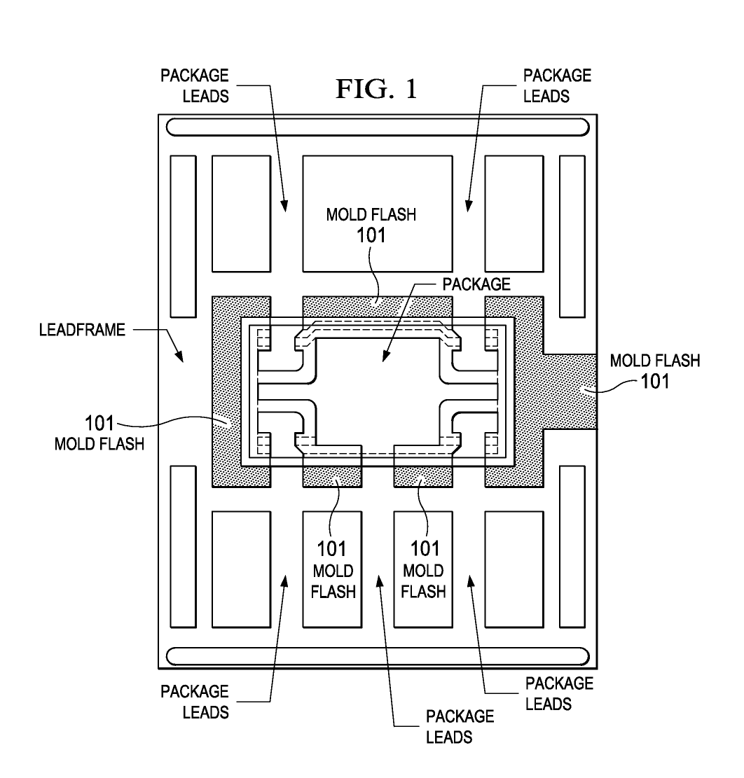

There is always a need to improve integrated circuit packaging processes. When current processes are used to package integrated circuits, a structure is formed as shown in FIG. 1. An Existing normal leadframe after molding creates an area 101 between the dambar 111 and the molded body called mold flash 101 that must be removed during trim and form process.

During dambar 111 cut, this mold flash 101 will break and tend to leave some loose mold flash. The loose mold flash that drops during dambar cut and trim/form processes will cause quality issue such as dented leads, lead contamination (embedded with loose mold flash) and bend lead. The loose mold flash will sometimes cause damage to dambar cut and trim/form tools as well.

Currently, for leaded packages, there is no convenient way to avoid the above mentioned mold flash.

A method to reduce the amount of mold flash created during the molding process is to place a protrusion 102 from leadframe dambar extended into the un-avoided mold flash 101 area. This helps minimize volume of mold compound in the mold flash area. The protrusion disclosed in this invention can extend 0.15 millimeters (mm) inwardly from the dambar toward the molded body of the package and centered between the adjoining leads. When dambar is cut, mold flash that is sticking to the protruded leadframe will fall off together with dambar that is being punched away. This will further reduce mold flash in between leads of package.

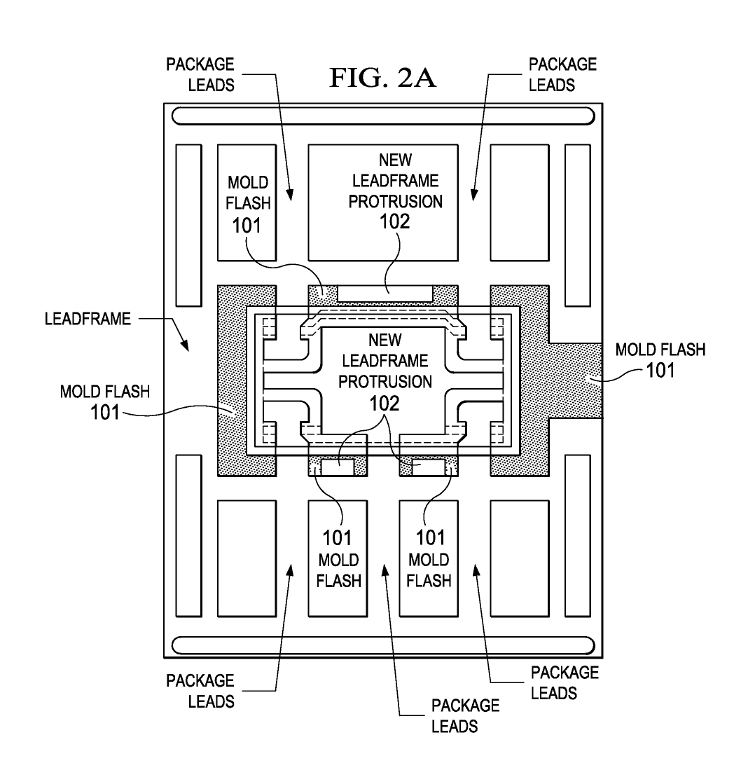

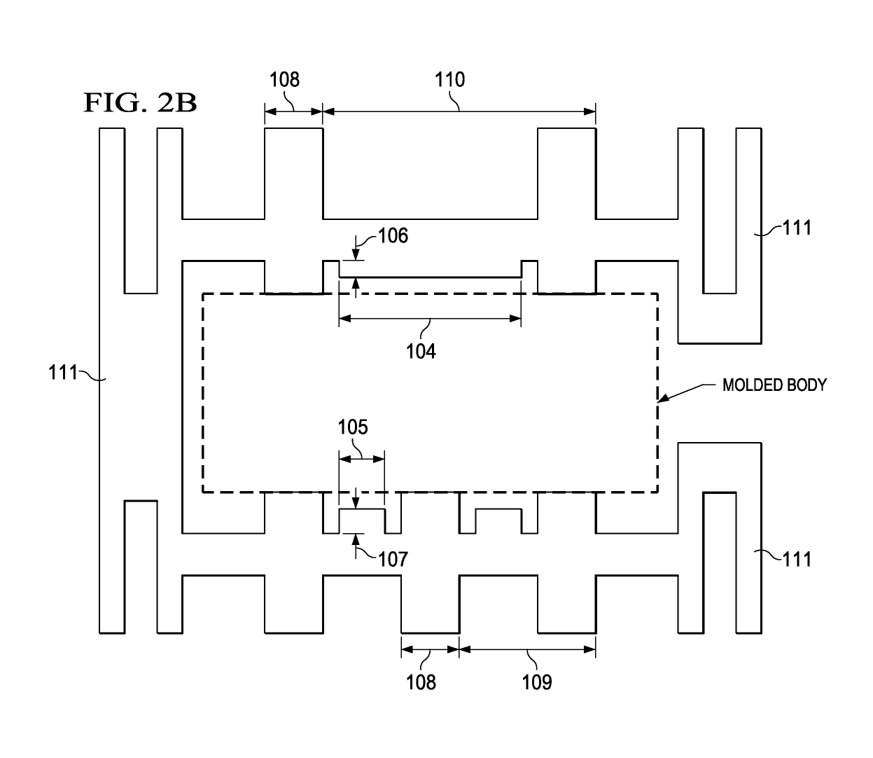

FIG. 2A shows a new leadframe with protrusion 102. One of ordinary skill in the art can see that the mold flash area 101 is now reduced because it is being filled by a protrusion 102 at the dambar.

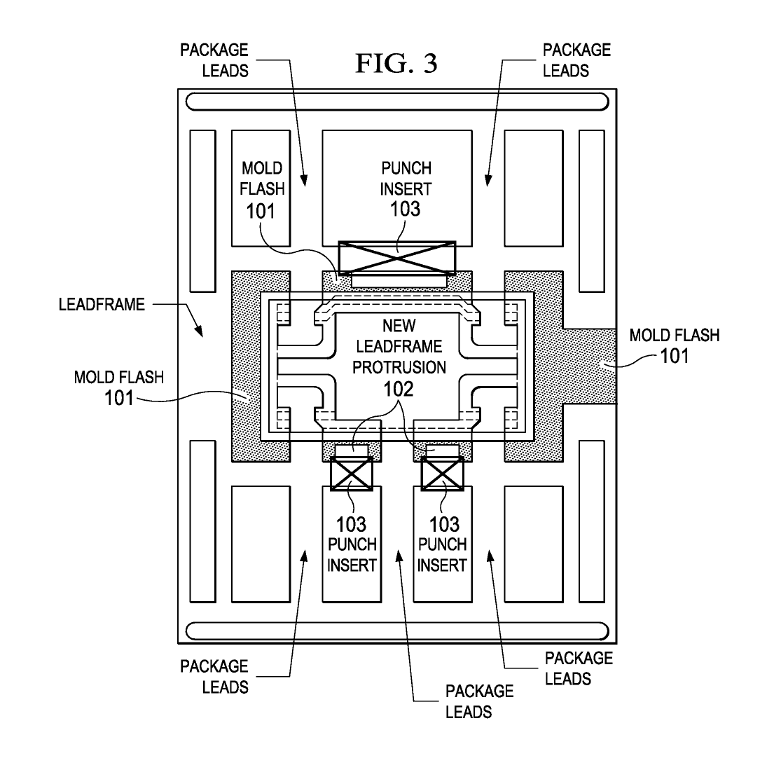

During dambar cut, punch insert 103 shown in FIG. 3 will shear off the dambar area. Since mold flash adheres well to additional protrusion 102, it will fall off together will dambar when it is cut. This helps to minimize amount of mold flash compared to the mold flash created between the package body and the dambar shown in FIG. 1.

FIG. 2B shows the leadframe of the molded package in FIG. 2A with an opaque molded body i.e. the internal structure of the molded body is not visible as it is in FIG. 2A. For a leadframe with 0.368 mm wide leads 108 and a 0.965 pitch 109 of the leads, the protrusion can be 0.3 mm wide, and centered between and spaced apart from the two adjacent leads with a 0.15 mm projection 107 toward the molded body of FIG. 2B. For a leadframe with 0.368 mm wide leads 108 and a 1.93 pitch 110 of the leads, the protrusion can be 1.25 mm 104 wide centered between and spaced apart from the two adjacent leads with a 0.15 mm projection 106 toward the molded body of FIG. 2B.

As can be seen by one of ordinary skill in the art, the problem with mold flash enclosed within the dambar and package body can be solved by creating a leadframe with protrusions from dambar towards the mold flash area to minimize mold flash volume and minimized loose mold flash that may potentially cause quality issue.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A molded semiconductor package comprising:
a molded portion of the package, having an edge;
a leadframe having first and second surfaces and a thickness therebetween and a plurality of leads;
a dam bar separated from the molded portion of the package edge, the dam bar having transverse portions extending between the adjoining leads of the plurality of leads; and
projections of leadframe material extending inwardly from the dambar toward the edge of the molded portion of the package, wherein the projections are centered and spaced apart from the adjoining leads of the plurality of leads.

2. The molded semiconductor package of claim 1, wherein the projections of leadframe material extends inwardly 0.15 millimeters (mm) from the dambar towards the molded portion of the package.

3. The molded semiconductor package of claim 1, wherein the width of the plurality of leads of the leadframe is 0.368 mm and the pitch of the leads is 0.965 mm.

4. The molded semiconductor package of claim 3, wherein the width of the projection of the leadframe is 0.3 mm

5. The molded semiconductor package of claim 1, wherein the width of the plurality of leads of the leadframe is 0.368 mm and the pitch of the leads is 1.93 mm.

6. The molded semiconductor package of claim 5, wherein the width of the projection of the leadframe is 1.25 mm
